(19) United States
(12) Patent Application Publication
(10) Pub. No.: US 2026/0244797 A1
(43) Pub. Date: Aug. 20, 2026

(54) METHOD AND DEVICE FOR TESTING THE FUNCTION OF A SYSTEM, USE OF A HEAD-MOUNTED DISPLAY, HEAD-MOUNTED DISPLAY, AND METHOD AND DEVICE FOR VISUALLY DISPLAYING 3D DATA

(71) Applicant: SKAN AG, Allschwil (CH)

(72) Inventors: Björn Glienke, Basel Stadt (CH); Corinna Erika BRAUN, Liestal (CH); Dennis Fabio KIPPER, Basel (CH)

(73) Assignee: SKAN AG, Allschwil (CH)

(21) Appl. No.: 19/159,681

(22) PCT Filed: Feb. 28, 2024
(86) PCT No.: PCT/EP2024/055071

§ 371 Date: Aug. 26, 2025

(30) Foreign Application Priority Data
Feb. 28, 2023 (DE) 10 2023 104 860.0

(51) Int. Cl. G06F 30/12; G06F 3/01; G06T 7/73; G06T 19/00; G06T 19/20

(52) U.S. Cl. CPC G06F 30/12; G06F 3/014; G06F 3/016; G06T 7/73; G06T 19/006; G06T 19/20; G06T 2207/30196; G06T 2207/30204; G06T 2219/2004; G06T 2219/2016

(57) ABSTRACT

A method for testing the function of a system (1). In the method, real models (7, 8) of details of a virtual 3D model (39) of the system are created, with the spatial position and orientation of these real models being captured by a 3D measuring device (11) during the function testing. The determined orientations and positions can be used to manipulate virtual objects (3, 4) in the 3D model (39) in order to display a visual impression (20) in a virtual reality of handling or manipulating the real models (7, 8).

### CROSS-REFERENCE TO RELATED APPLICATIONS

This application is a 371 National Phase of International Application No. PCT/EP2024/055071, filed Feb. 28, 2024, which claims priority from German Patent Application No. 10 2023 104 860.0, filed Feb. 28, 2023, both of which are incorporated herein by reference as if fully set forth.

### TECHNICAL FIELD

The invention relates to a method for testing the function of a system.

The invention further relates to a device for testing the function of a system.

The invention further relates to a head-mounted display and its use.

The invention further relates to a method for visually displaying 3D data and to a corresponding device.

### BACKGROUND

It is known from practice to carry out functional tests, in particular on pharmaceutical systems, on cardboard and/or wood models, before the often complex manufacturing is started.

In practice, cardboard and/or wood models are known for the above-mentioned method.

Head-mounted displays are known from practice, for example, as VR (virtual reality) glasses, AR (augmented reality) glasses and MR (mixed reality) glasses, for example, which can be used to display virtual, spatially assigned data alone or in conjunction with real scenes in a visually perceptible manner for an observer for a wide variety of purposes, often in the entertainment industry, in order to generate a spatial impression. For example, head-mounted displays are described in the German edition of Wikipedia. Thus, a head-mounted display can be characterized, for example, as a visual output device to be worn on the head. Such a device may be set up, for example, to present images either on a screen near the eyes or by projection onto the retina in order to complement (AR, MR) or to replace (VR) a natural visual impression of an observer with an artificially generated impression.

It is known from practice to use such methods and devices in the entertainment industry sector, in particular with the head-mounted displays already mentioned, in order to present three-dimensional data in a directly tangible way.

### SUMMARY

The invention is based on the object of simplifying the functional testing of complex systems.

In order to achieve the stated object, according to the invention one or more of the features disclosed herein are provided. In particular, in order to achieve the stated object in a method of the type described at the outset, it is therefore proposed according to the invention that the system is represented as a virtual 3D model comprising virtual objects, wherein a real model is provided by at least one virtual object, and wherein a virtual body is aligned with the real model at recurring times using a 3D position measurement and the at least one virtual object is linked to the virtual body and is brought into a desired position relationship with the virtual body, wherein the link between the virtual body and the at least one virtual object is changed by a user. Thus, the invention makes it possible to haptically experience virtual modeling which allows real functional tests without requiring a complete real image of the system to be tested. This can significantly simplify the functional test, since the entire system does not have to be constructed as a real model.

It can be said in general that the links mentioned can also refer only to a subset of degrees of freedom of movement of the respective objects or bodies or force a complete definition. For example, a desired positional relationship can also mean that only parts of the movement are reconstructed (e.g. only X and Y axes, no rotation). This takes place for the hologram as well as for the target of the shoulder ring (glove port).

For example, the real model can be tilted, for example, with respect to the plane of a pane of glass, such that, when the link is activated, an associated virtual object would be pulled out of the (virtual) plane of the pane. Provision may be made here for a boundary condition to be formulated, which allows this object to be aligned with respect to the virtual body only in certain degrees of freedom and fixes it in the degrees of freedom of the pane, such that the virtual object, such as a shoulder ring or a glove port, remains in the pane. Thus, disturbing visual impressions can be avoided.

For example, it is possible to dispense with real objects that do not come into contact with a user in a particular test because they would be too far away. For example, the concept of activating a link makes it possible in this case to couple the virtual world to the real world, which makes details of the 3D model haptically tangible by means of suitably positioned real models. The concept of deactivating a link makes it possible, for example, to exchange virtual objects and thus use a very limited supply of real models multiple times, for example at different locations in an industrial system, in particular when design details are used multiple times.

The user who activates or deactivates the links may be, for example, an observer of the (virtual) system, in particular a person who tests the function of the system, or an assistant who maintains a computer-implemented 3D engine or generally software that implements the invention. For example, a 3D engine, also known as a graphics engine, can be characterized as an integrated or externally stored program code which is responsible for calculating the graphics interface in parallel with the actual program.

For example, a virtual object can be characterized as a functional and/or design part of the 3D model. Examples may be static parts such as shoulder rings or boundary walls of an isolator as a special (pharmaceutical) system or moving parts such as doors, in particular of transfer ports or rapid transfer ports (RTP for short; also known as an alpha-beta port system) or airlocks, or functional stations such as filling stations, closure stations, or material stores or manipulators. This list is not exhaustive. Other examples can be advantageously used.

For example, a virtual body can be characterized as a rigid body formed from measuring points in a fixed arrangement in relation to one another.

For example, provision may be made for the link to be changed by activating (or starting) and/or deactivating (or ending) it. This makes it possible to establish or release a spatial coupling between the virtual object and the virtual body in a virtual space. Since the virtual body is coupled to a real model via the 3D position measurement and forcibly reconstructs its attitude and position changes in a virtual space, the link can thus—in the case of activation—couple the virtual objects of the 3D model to reality or—in the case of deactivation—detach the virtual objects from reality.

In one advantageous configuration, provision may be made for the linking of the virtual body to the at least one virtual object to comprise forcing a desired positional relationship on a position and/or an attitude of the virtual object in relation to the virtual body. This makes it possible to create an impression of a virtual object concomitantly moving with a haptically tangible real model. This can be used, for example, to test real work steps on a 3D model for feasibility. This forcing, in particular if it is limited in time, can also be used as a simple means of transferring a change in the real model, such as an ergonomic improvement, to the virtual object. The forcing can relate to all degrees of freedom of movement or to a subset of the degrees of freedom of movement, in particular in order to comply with boundary conditions.

Generally, a position of a virtual object or a real model can be described, for example, by three coordinates of a selected point, in particular a center of gravity, a center point or another distinguished or special point. An attitude of a virtual object or a real model can be described, for example, by angle specifications pertaining to an orientation in relation to rotations around the selected point to which the position refers, and/or by specifications relating to a position of another point on the virtual object or the real model, which may be in a fixed relationship with the selected point. A pose can be described, for example, by a position and an attitude.

For example, provision may be made for the position and/or attitude of the virtual object to be set to the position and/or attitude of the virtual body. This makes it possible to achieve dislocation-free following or concomitant movement.

Alternatively or additionally, provision may be made for the forcing to be triggered by making a request. It is thus possible to exchange virtual objects and/or real models during linking.

Alternatively or additionally, provision may be made for the forcing to be carried out permanently, for example at recurring times, preferably automatically. It is thus possible, for example, to have the virtual object concomitantly conveyed with the virtual body over a movement section.

In one advantageous configuration, provision may be made for a set-up step to define the virtual object to which a virtual body can be linked. Thus, a set of real models can be expanded.

In one advantageous configuration, provision may be made for a set-up step, for example the set-up step already mentioned, to define how a virtual object can be linked to a virtual body. Thus, an exact alignment of the virtual body with the virtual object can be defined. For example, a location of markers that span a virtual body can be defined on a matching virtual object. Thus, new real models can be subsequently incorporated.

In one advantageous configuration, provision may be made for a linkability of a virtual body to at least two virtual objects to be set up. Thus, operation of a complex arrangement comprising a plurality of virtual objects can be reconstructed or simulated by virtue of the arrangement, optionally with different virtual objects, being able to be docked to reality, for example to real models. In this case, docking results, for example, from the fact that the coupling between the virtual body and the real model is fixed.

In one advantageous configuration, provision may be made for a link between a virtual body and a virtual object to be able to be activated or started and/or deactivated or ended independently of a link between a further virtual body and a further virtual object. It has emerged that a link should be deactivated if the real model is not intended to be moved in practice, in order to avoid artefacts from image processing.

In one advantageous configuration, provision may be made for a number of virtual, in particular linkable, objects to not be less than a number of virtual bodies. The two numbers can thus be the same, or the number of virtual objects can be greater than, in particular greater than three times, the number of virtual bodies. This makes it possible to simulate operating processes on complex arrangements such as production lines or isolators without having to construct the entire system. This saves preparation time, material and space requirements. In addition, changes can be implemented more flexibly and a structure can be transported with little effort and is therefore not tied to a location. This saves costs.

In one advantageous configuration, provision may be made for at least two real models to be provided. Thus, processing operations that relate two real models to each other can be simulated, for example the opening of a door.

Provision made be made for an associated virtual body to be realized in each case.

In one advantageous configuration, provision may be made for at least two real models to be brought into a spatial relationship with each other, which is predefined by a virtual spatial relationship of at least two virtual objects.

In this case, provision may be made for the at least two virtual objects to be linked to at least two virtual bodies which belong to the at least two real models.

In one advantageous configuration, provision may be made for at least two real models to be movable with respect to each other with forced guidance. A non-exhaustive list of examples of forced guidance includes an articulated connection of a door to its frame, such as in an RTP, or a rail guide of a wagon.

In one advantageous configuration, provision may be made for at least two real models to be movable with respect to each other in a limited way. Such a limitation may result, for example when an isolator glove is used, from the fact that a hand, to which a real model with markers can be attached, can be inserted only so far through a shoulder ring, to which the glove is attached, until the material of the glove has maximum tension.

In one advantageous configuration, provision may be made for the mobility of a user to be restricted during use by at least one real model. This makes it easy to test whether a movement can be carried out in the simulated system. An example is a test of the action range on a shoulder ring that keeps a user away.

In one advantageous configuration, provision may be made for the linking to be deactivated over a preferably defined or indefinite period of time. This makes it possible to align a real model, in particular with respect to a further real model, the virtual body of which is already linked, in order to make the real model coincide with a virtual world, in particular the virtual 3D model, to which the at least one virtual object belongs, in such a way that the further real model still coincides with this virtual world.

In this case, provision may be made for deviations between the at least one virtual object and the virtual body when the link is deactivated to be displayed This can be used, for example, to move a real model to a desired position, such that a desired relationship with a virtual object is established.

In one advantageous configuration, provision may be made for the link of the virtual body to the at least one virtual object to be replaced by another link of the virtual body to another virtual object. This makes it possible to re-use a real model for a test on other virtual objects of the 3D model. This means that it is not necessary to completely construct the system. This can save space and time for creating the real models, and can allow the functional test to be performed at remote locations or by users remote from one another. It also saves costs involved in producing and assembling the models. There are also technological advantages; for example, a cut can be made in the virtual model or a hologram can be displayed for better intelligibility.

In one advantageous configuration, provision may be made for the 3D model to be subjected to an isometric transformation, when the link is replaced by another link, until the virtual body and the other virtual object are made to coincide at least within a tolerance range. This allows the user to be moved in the virtual world without the user having to change their location in the real world. This makes it easy to use real structures that have already been constructed for further tests without modifications. It is then easy to adapt the existing real models to the position and/or attitude of the new virtual objects, as described above.

Such an isometric transformation may comprise, for example, rotation and/or displacement. This means that the relocation simply corresponds to any change in location in the real world.

Only isometric transformations that obtain an orientation, i.e. do not mirror it, for example, are preferably permitted. Changes for which there is no equivalent in the real world are thus blocked.

In one advantageous configuration, provision may be made for an attitude of the real model to preferably be changed manually or automatically until the associated virtual body is made to coincide with the at least one virtual object or with the other virtual object. This makes it possible to align the real models in such a way that a haptic impression in interaction with the real model coincides with a visual impression when viewing the virtual object.

For example, a shoulder ring can first be made to coincide with the 3D model by activating a link to the relevant virtual object. Subsequently, a further shoulder ring or another part, for example a door or a functional unit to be manipulated, can be changed as a real model in such a way that this real model is made to coincide with its corresponding virtual object and that the real model positioned and/or aligned in this way is included in the virtual world.

In this case, provision may be made for a link between the virtual body and the virtual object or the other virtual object to then be activated. Thus, a movement of the real model can then be reconstructed by the virtual object. Thus, an observer of the virtual world can have the feeling of actually moving or manipulating the virtual objects, since the observer receives haptic or tactile sensory information matching the visual sensory information.

In one advantageous configuration, provision may be made for a plurality of virtual bodies to be linked to a respective virtual object of the 3D model, wherein the individual links are changed, in particular activated and/or deactivated, independently of each other. Thus, different real models, for example two shoulder rings, can be set independently of each other, and/or individual real models can be selected as moving parts of the system that require the virtual object to be concomitantly conveyed, while other real models are or remain usable as real world reference points at which the virtual world can dock.

In one advantageous configuration, provision may be made for an update of coordinates of the at least one virtual object to be output. This can be used, for example, to edit design data relating to the 3D model. This means that adjustments and changes to the system that are necessary in terms of ergonomics and/or process economy can be made easily, without the need to create a new complete model in the real world.

In one advantageous configuration, provision may be made for it to be a system for the pharmaceutical sector, preferably for filling drugs into packages, and/or in combination with a protected space, preferably an isolator. Regulatory requirements and/or ergonomic boundary conditions can be easily tested here in workflows.

Alternatively or additionally, the stated object is achieved by a method for testing the function of a system, wherein the system is represented as a virtual 3D model comprising virtual objects, wherein a real model is provided by at least one virtual object, and wherein a virtual body is aligned with the real model at recurring times using a 3D position measurement and the at least one virtual object is linked to the virtual body and is brought into a desired positional relationship with the virtual body, wherein a real model corresponding to the at least one virtual object is produced and is provided with identifiable features, in particular markers, for a 3D position measurement, and a correspondence between the identified features and the at least one virtual object is stored. This makes it possible to easily produce and incorporate details of the system that are relevant to the tests and for which physical interaction is desired. The identifiable features can be easily used to generate the virtual body that is intended to be linked to the object.

This aspect can be advantageously combined with the previously described aspect. For example, a real model prepared for use by markers is easily usable in the method according to the invention by activating the link. The markers can be realized, for example, by preferably two-dimensional or three-dimensional markers.

Preferably, the real model is produced in an additive method, in particular from CAD data or other data relating to the virtual object. This makes it possible to realize the 3D model as accurately as possible in terms of detail in order to also make details haptically tangible. An advantageous variant is also to use the real model and to provide said model with markers directly in order to achieve an even better haptic experience.

Alternatively, a virtual object can also be derived from a 3D scan of a real model. Thus, a prototype or a sample from a manufacturer can be used directly without the need for CAD data to be available, and/or complex 3D printing of a complex object can be avoided.

In one advantageous configuration, provision may be made for the identifiable features to be formed at predetermined positions of the real model. This makes it possible to quickly and easily incorporate or create a correspondence between the virtual body, which may be given by the features, and the virtual object on which the positions of the features can be recorded.

In one advantageous configuration, provision may be made for at least one position of the features formed on the real model to be measured. This can be carried out, for example, using a 3D camera. The measurement allows any markers to be applied. This can simplify the preparation of the real models for use.

In one advantageous configuration, provision may be made for an operator to wear a glove and/or a hand tracking device (smartglove, metaglove, motion capture glove, fingertracking device). Alternatively, direct tracking of hands is also possible. The detection of hands is favorable for rendering manipulation actions as realistically as possible in the virtual world. Isolator or shoulder gloves can also be used, for example to create a realistic replica of the resulting physical limitations.

In this case, provision may be made for a 3D position, in particular a position and an attitude, of one or more fingers and/or a hand and/or an arm to be determined recurrently. This makes it easy to integrate hands and/or arms, which are used to carry out manipulations and/or for which collision tests are required, into the virtual world.

For example, this can be achieved by detecting a glove, in particular the glove already mentioned, and/or a hand tracking device, in particular the hand tracking device already mentioned. Realistic manipulation actions can thus be displayed virtually.

In one advantageous configuration, provision may be made for the 3D model to represent a shoulder ring, to the position of which a real shoulder ring is adjusted, in particular in an upstream set-up step, and/or for an operator to insert an arm through the shoulder ring, preferably in a manipulation glove fastened to the shoulder ring.

In one advantageous configuration, provision may be made for the recording pose of the observer to be defined relative to the shoulder ring. Thus, the observer's position and attitude can be used as a reference for displaying the virtual objects.

In one advantageous configuration, provision may be made for the at least one virtual object to be a door of a transfer port or a lock. Other details of a system that need to be manipulated during use can also be used, for example air samplers, agar plates, sampling units, filling stations, pump bodies, hoses, generally semi-stationary parts (for example parts whose mobility is restricted by joints or guides) or freely moving parts of the system.

In general, the real models can be divided into those which are movable with respect to a reference point, for example a boundary of the system, and/or with respect to an entry, in particular with respect to a shoulder ring, and those which are immobile.

In one advantageous configuration, provision may be made for the 3D model to have a further virtual object, for which a further real model is provided, wherein the real model is arranged movably relative to the further real model. Thus, individual real models can be used as reference points for connecting the virtual world and other real models can be used for spatially accurate manipulations in a virtual world brought to register with reality.

In one advantageous configuration, provision may be made for the further real model to be at least partially immobile and/or at least partially movable with respect to a demarcation of the system. Thus, a demarcation can be used as a reference point or reference surface in order to establish a correspondence between the virtual world and the real world.

A non-exhaustive list of examples of at least partially movable components of a system, which can be advantageously used as a real model, comprises a shoulder ring and/or a door frame of a transfer port and/or a door, in particular of a transfer port or an airlock door, and/or a latch and/or a Petri dish, an air sampler, at least one agar plate, a sampling, a pump body, at least one hose.

A configuration of potentially independent inventive quality proposes achieving the stated object by way of a method for testing the function of a system, in particular as described above, having the following steps of: providing CAD data for the system, creating at least one real model for at least some of the CAD data, setting up the at least one real model in a 3D measuring apparatus, displaying a virtual 3D model created from the CAD data by processing at least 3D measurement data from the 3D measuring device. This makes it possible to test the function of a complex system, based on haptic impressions of the real model, with little material expenditure.

In one advantageous configuration, provision may be made for a field of view of a head-mounted display to be determined, preferably using the 3D measuring apparatus. This makes it possible to embed an observer and/or operator in a virtual scene of virtual objects of the CAD model.

In one advantageous configuration, provision may be made for the 3D model to be displayed with respect to a field of view of a head-mounted display. This allows the 3D model to be realistically viewed from an observer's position.

In one advantageous configuration, provision may be made for a change to the at least one real model to be automatically reconstructed on the 3D model. Thus, changes in the real world can be easily reconstructed in the virtual world in which the 3D model is defined. An observer can thus be given the impression that the virtual objects can be changed by means of a-haptically tangible-change to the associated real model, for example which corresponds to the linked virtual body. This makes it possible to perform functional tests on complex industrial systems, such as pharmaceutical systems, with little use of materials, time and space.

Here or in general, provision may be made for modified design data to be generated from the modified 3D model or modified virtual objects and to be output. This makes it possible to specify design changes that have arisen during the functional test.

In one advantageous configuration, provision may be made for the 3D measuring device to be transported in a fixed measuring set-up prior to installation. Thus, a device according to the invention can be easily transported to a remote location, for example for a functional test in situ.

The object stated at the outset is alternatively or additionally achieved by a device for testing the function of a system, wherein the system is present as a virtual 3D model, having a 3D measuring device, at least one real model of a virtual object of the 3D model, an apparatus for automatically integrating a virtual body, captured for the real model using the 3D measuring device, in the 3D model, an apparatus for automatically concomitantly conveying the virtual object with the virtual body, and an apparatus for visually displaying the 3D model, in particular a 3D engine. Thus, means are provided in order to test a haptically tangible, virtually representable system.

In one advantageous configuration, provision may be made for a means to be designed to activate and/or deactivate a link between the virtual body and the at least one virtual object. This allows an operator to easily determine how the virtual world of the 3D model is intended to be associated with reality.

In one advantageous configuration, provision may be made for a head-mounted display to be set up to generate a field of view on the 3D model. Thus, a natural observer's position can be realized.

In one advantageous configuration, provision may be made for an apparatus for generating a field of view on the 3D model to be fed with measured values from the 3D measuring device in relation to a head-mounted display, in particular the head-mounted display already mentioned. This allows the 3D model to be viewed from a human observer's position.

In one advantageous configuration, provision may be made for an apparatus to be designed for isometric transformation of the 3D model relative to the field of view. This allows relocation of the 3D model or a virtual change of position by an operator of the system.

The object stated at the outset is alternatively or additionally achieved by using a head-mounted display, in particular VR, XR and/or AR glasses, and a 3D measuring apparatus, which is preferably stationary and/or works independently of the head-mounted display, for creating a virtual view of a 3D model of a system in the head-mounted display, wherein individual virtual objects correspond to real models that are captured by the 3D measuring apparatus. Thus, a means for a haptically controllable, virtual functional test on a system represented as a 3D model is possible.

In particular, this can be used to test the function of a preferably pharmaceutical system, preferably in a method according to the invention, in particular as described above and/or below and/or described below, and/or in a device according to the invention, in particular as described above and/or below and/or described below. The invention can save considerable cost, time and space here, since pharmaceutical systems, in particular as controlled spaces or in controlled spaces, for example RABS (restricted access barrier systems) or isolators, often have large spatial extents. This makes a traditional structure made of cardboard and/or wood complex.

Preferably, the invention uses a head-mounted display, for example VR, AR and/or XR glasses, having at least one marker, in particular having more than two markers, for preferably extrinsically determining a recording pose. Three markers are often sufficient to clearly determine a position and an attitude of a real model. However, it is favorable to apply more than three markers, in particular for more complex real models. It is thus possible for a field of view of the head-mounted display to be easily embedded in a virtual space of the virtual 3D model by way of a 3D measurement. This gives an observer a realistic impression of the system from their observer's perspective.

The marker can be active. This makes it possible to individually capture the individual head-mounted displays. This makes it easy to replace units without re-training being required and/or the system having to be re-aligned. Definition of a single center as a reference for multiple encodings is thus also possible. This single center can then be used for mapping the virtual body to a field of view and ultimately for embedding without training for each marker.

The marker can alternatively or additionally also be passive. This makes it possible to increase a service life of the head-mounted display since fewer resources are consumed during operation. Markers can also be applied in different positions on different head-mounted displays in this case, thus permitting individual detection. A standardized fastening kit for connecting glasses and markers means that embedding is possible without training or with only very little effort. Another advantage of passive markers is also their low weight, which has a positive effect on e.g. the wearing comfort of the head-mounted display.

The object stated at the outset is alternatively or additionally achieved according to the invention by a method for visually displaying 3D data, wherein a field of view of a head-mounted display, in particular VR and/or XR and/or AR glasses, is intrinsically determined at recurring times and information moving concomitantly with the field of view is displayed in the head-mounted display, wherein a recording pose, predefining the field of view, preferably at recurring times, of the head-mounted display is determined and is compared with the field of view. It is thus possible for the field of view to be embedded in a virtual world in a spatially accurate manner using the available computing capacities of a head-mounted display. The invention has the advantage that a spatial relationship between the observer and those virtual objects which are currently not in the field of view of the observer, defined by a recording pose of the head-mounted display, can also be determined.

An intrinsic determination can be characterized, for example, by the fact that associated sensors are concomitantly moved and/or are aligned in the direction of the field of view and/or that the field of view can be calculated using on-board means of the head-mounted display.

The field of view of the head-mounted display can be given here, for example, by the visual field of an observer whose head position corresponds to a current recording pose of the head-mounted display when the latter is in the position of use. For example, the recording pose can refer here to the position and attitude of a forward direction of the head-mounted display.

This method may be designed or carried out, for example, as a part of a method according to the invention for testing the function of a system, in particular as described herein and/or described below.

In one advantageous configuration, provision may be made for the recording pose to be determined using a 3D measuring apparatus that is formed independently of the head-mounted display and/or is stationary. This allows the head-mounted display to be detected at all times and on all sides, and the field of view to be embedded without interruption.

For example, the 3D measuring device may comprise at least one or more cameras. In general, the use of multiple cameras can be said firstly to improve the accuracy of the measurement and secondly to be less susceptible to concealment of details by other details.

3D measuring devices are known per se for spatial detection of the position and attitude of real models. One possibility is to create two-dimensional images of the real models from different recording poses, to identify the respective models in these images, for example by means of applied markers, and to then solve a system of equations that describes these images as recordings of a common real model, wherein the shape, for example the position of the individual markers, is included as an unknown and the image positions are treated as input variables. Alternatives to this are, for example, use of structured light, the pattern of which on the real models allows conclusions to be drawn about an attitude and a position of the real models. Methods using propagation time measurements of signals are also known.

In one advantageous configuration, provision may be made for the recording pose to be determined using a measuring apparatus which moves concomitantly and/or is independent of the determination of the field of view. This reduces the equipment structure of the device according to the invention.

In one advantageous configuration, provision may be made for the intrinsic determination to be carried out by means of at least one concomitantly moving sensor, in particular a camera and/or a motion and/or acceleration and/or position sensor. It is therefore possible to use inherently known systems for determining the field of view and the change therein with a head movement.

In one advantageous configuration, provision may be made for the recording pose to be measured by means of active markers on the head-mounted display. Active markers offer the advantage of better distinguishability and easy changing of identifications.

In one advantageous configuration, provision may be made for the recording pose to be measured by means of passive markers on the head-mounted display. Passive markers help to save energy for operation, thus extending a service life, while the device remains operational.

In one advantageous configuration, provision may be made for the recording pose to be measured by means of a stationary measuring device, in particular by means of stationary cameras.

In one advantageous configuration, provision may be made for the intrinsic determination of the recording pose to be measured by means of concomitantly moving cameras of the head-mounted display.

The object stated at the outset is alternatively or additionally achieved according to the invention by a method for visually representing a system and/or a method as part of a method described above and/or described below, wherein a field of view of a head-mounted display, in particular VR and/or XR and/or AR glasses, is intrinsically determined at recurring times, and wherein an air flow is calculated and visually displayed as preferably concomitantly moving 3D data in the head-mounted display. An advantage of this is that the influence of a work process on an air flow is immediately evident and/or controllable.

It is known to use air flows in controlled environments to prevent contaminants from being transferred to areas requiring special protection. The invention allows said air flows to be checked, since air flows are also influenced, for example, by mobile functional units and/or a user.

In one advantageous configuration, provision may be made for the head-mounted display to be connected to a preferably stationary processing unit for the purpose of transmitting measurement data relating to the recording pose and/or image data for the head-mounted display. This makes it possible to transfer computing routines to stationary units with greater capacity. In this case, data can be transmitted, for example, wirelessly or in a wired manner.

In one advantageous configuration, provision may be made for the 3D data to comprise a 3D model of a system and/or for the 3D data to also comprise AR metadata for components of a system, in particular the system already mentioned. The use of a 3D model enables a realistic visual representation of a system in the virtual space. The use of AR metadata also allows data that go beyond the mere image content, such as warnings, messages or instructions, to be shown or displayed. This makes it easy to change to an observer's language or permits shown information to be altered on the basis of an operating state of the system, for example. Flow data for an air flow can also be displayed as 3D data, in particular in the form of flowlines.

In one advantageous configuration, provision may be made for a virtual display of the 3D data to be superimposed on a real field of view using the head-mounted display, in particular a head-mounted display according to the invention, for example as described above and/or described below. This means that MX or AR applications are possible.

Alternatively or additionally, provision may be made for a real environment to be shielded using the head-mounted display, in particular a head-mounted display according to the invention, for example as described above and/or described below. This means that VR applications are possible.

In addition, in one of the methods described, provision may be made for a real model, for example one of the real models already mentioned, to be adjusted by motor. Thus, setting to a position and/or attitude of a virtual object can be carried out more easily and/or more accurately.

Alternatively or additionally, in one of the methods described, provision may be made for a real model, for example one of the real models already mentioned, to be adjusted, preferably by motor and/or automatically, until a preferably automatically captured deviation in a position and/or attitude of a virtual body from a corresponding virtual object is within a tolerance range. A real model can therefore be incorporated automatically into the method.

In the case of the shoulder rings described in more detail further below, for example, these two configurations can be advantageously used together or each individually.

Alternatively or additionally, in one of the methods described, provision may be made for a virtual light beam to be generated, in particular in which case it is automatically checked whether the virtual light beam is interrupted. This allows a functional test to be carried out even closer to reality.

In order to achieve the object stated at the outset, the invention also provides a device for visually displaying 3D data, having a head-mounted display which is set up to determine a concomitantly moving field of view, having an apparatus for determining a recording pose of the head-mounted display, and having an apparatus for comparing the recording pose with the field of view. It is therefore possible to embed a field of view in a virtual world of virtual objects in a spatially accurate manner with low computational requirements for the head-mounted display. This can be used, for example, to show information and messages in the correct location.

The device may be designed here, for example, as part of a device according to the invention for testing the function of a system, for example as described above and/or described below.

One advantageous configuration can be formed with a 3D engine for visually displaying the 3D data in the field of view. Known algorithms can thus be used to control visual displays.

One advantageous configuration may be formed with a preferably stationary 3D measuring device for determining the recording pose. A stationary 3D measuring device can be configured with a larger spatial coverage, for example by spatially distributing corresponding cameras.

One advantageous configuration may be formed with an apparatus for generating a virtual space for a virtual body captured using a 3D measuring device, for example the 3D measuring device already mentioned. Thus, real models and their changes can be captured. This can be used, for example, to connect a virtual world to a real world. An example of a 3D measuring device is the combination of the Prime^{X} 13 and/or Prime^{X} 13W cameras from OptiTrack (NaturalPoint, Inc., P.O. Box 2317, Corvallis, OR 97339) with the motion capture software Motive from OptiTrack.

One advantageous configuration may alternatively or additionally be formed with an apparatus for generating a virtual space for visually displaying the 3D data. It is therefore possible to provide a scene for generating virtual visual impressions.

One advantageous configuration can alternatively or additionally be formed with an apparatus for establishing a correspondence between two virtual spaces, preferably the virtual spaces already mentioned, in particular for embedding the virtual bodies in the virtual space for the virtual display. This provides an easy-to-use means in order to modify virtual objects by manipulating real, corresponding models.

One advantageous configuration may be formed with an apparatus for embedding a field of view of the head-mounted display in the virtual space for the virtual display. This enables a faithful visual representation of the virtual world in the eyes of an observer as though they were actually seeing the virtual world.

One advantageous configuration may be formed with an apparatus for calculating an air flow, in particular for visually displaying the air flow. Air flows can thus be made visible, in particular as flowlines.

One advantageous configuration may be formed with means for carrying out a method according to the invention, in particular as described above and/or described below. This indicates a way of implementing the methods described.

In one advantageous configuration of one of the devices described, provision may be made for the device to be formed with an apparatus for adjusting at least one real model by motor. This allows precise and/or automatic and/or remotely triggered setting.

Alternatively or additionally, in one advantageous configuration of one of the devices described, provision may be made for the device to be formed with an apparatus for preferably automatically determining a deviation in a position and/or attitude of a virtual body from a corresponding virtual object. This means that incorporation can be supported in a computer-aided manner.

Alternatively or additionally, in one advantageous configuration of one of the devices described, provision may be made for the device to be formed with an apparatus for adjusting at least one real model by motor until a preferably automatically captured deviation in a position and/or attitude of a virtual body from a corresponding virtual object is within a tolerance range. It is therefore possible to incorporate real models in a fully automatic or semi-automatic manner.

Alternatively or additionally, in one advantageous configuration of one of the devices described, provision may be made for the device to be formed with an apparatus for a collision test for a virtual light beam. This can make it possible to simulate a light barrier, for example a light grid. For example, the 3D model may have the associated light barrier modules stored as virtual objects, and the light beam is automatically generated and monitored on the basis of the attitude and position of the light barrier modules.

### BRIEF DESCRIPTION OF THE DRAWINGS

The invention will now be described in more detail on the basis of exemplary embodiments, but is not restricted to the exemplary embodiments. Further exemplary embodiments arise from combining the features of individual or multiple claims with one another and/or with individual or multiple features of the exemplary embodiments.

In the drawings:

FIG. 1 shows a highly schematized representation of a device for testing the function of a system, having a head-mounted display and having a device for visually displaying 3D data,

FIG. 2 shows a more realistic individual representation of a real model of the device according to FIG. 1, with two adjustable shoulder rings and a 3D measuring device,

FIG. 3 shows a further more realistic representation of the arrangement according to FIG. 2 in a view of a glove from the side,

FIG. 4 shows a further more realistic individual representation of a real model of the device according to FIG. 1 with a movable door,

FIG. 5 shows an adaptation of a virtual object of a 3D model of the device according to FIG. 1 for achieving a desired positional relationship and for producing a connection,

FIG. 6 shows a modification of a real model in a device according to FIG. 1 for obtaining a desired positional relationship with respect to an associated virtual object and for producing a link,

FIG. 7 shows a device for visually displaying 3D data,

FIG. 8 shows a schematic representation of a 3D model in different alignments for a virtual change of location of an observer,

FIG. 9 shows a plan view of a detailed representation of a 3D model of a pharmaceutical system, and

FIG. 10 shows a schematic representation of a real space and two virtual spaces for explaining the invention.

### DETAILED DESCRIPTION

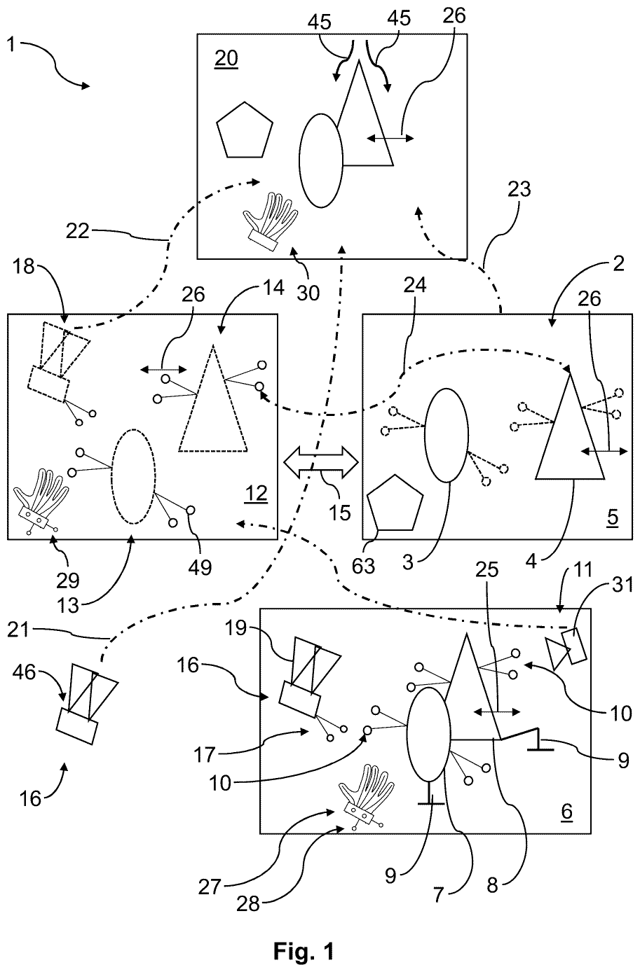

FIG. 1 shows a device for testing the function of a system, said device being denoted as a whole by 1.

A virtual 3D model 2 of a system 1 is composed of virtual objects 3, 4 and is provided in a first virtual space 5.

The virtual 3D model 2 is derived here from CAD data for an industrial system that are not represented further.

This system is represented only very schematically with the virtual objects 3 and 4 in order to explain the operating principle of the method according to the invention.

In fact, the system comprises components. A preferred application of the invention provides for the system to be a pharmaceutical system which may be intended, for example in a protected space or an isolator, to carry out certain methods, for example drugs repackaging/packaging drugs or assembling dispensing devices for medical preparations.

The first virtual space 5 contains a large number of virtual objects 3, 4. Further virtual objects 63 may also be present.

For some of these virtual objects 3, 4, corresponding real models 7, 8 are set up in a real space 6. No real models are set up for the further virtual objects 63.

These real models 7, 8 are attached to special stands 9 so that they remain at a desired position in the real space 6.

These stands 9 are not part of the virtual 3D model 2, because the virtual objects 3 and 4 therein are mounted on other design details, such as glass walls or boundary walls or tables. However, these glass walls, boundary walls and tables are not present in the real space 6.

The real models 7 and 8 are also equipped with additional markers 10 which have no equivalent in the virtual objects 3 and 4.

These markers 10 are intended for position and attitude detection by a 3D measuring device 11 which is installed in the real space 6. The 3D measuring device 11 detects these markers 10 and forms their position in a second virtual space 12. Therefore, the virtual objects 3 and 4 are not present in this second virtual space 12, but rather only positions of the markers 10, which are combined to form virtual bodies 13, 14, depending on which real models 7, 8 they are attached to.

A correspondence 15 is established between the first virtual space 5 and the second virtual space 12 and connects spatial points in the first virtual space 5 to corresponding spatial points in the second virtual space 12 and vice versa.

A head-mounted display 16 is also arranged in the real space 6, for example on the head of a user who is not represented further.

This head-mounted display 16, for example VR glasses, is not necessarily represented in the virtual 3D model 2, but also has markers 17 in order to detect its attitude and position in the real space 6 and to represent it in the second virtual space 12.

In other words, the second virtual space 12 has a virtual body 18 which represents the head-mounted display 16 via the markers 17.

The head-mounted display 16 generates a field of view 19 in a manner known per se to create a visual 3-dimensional impression for the user. This visual impression 20 is calculated from the measured attitude and position, i.e. the recording pose, of the head-mounted display 16 and the attitude and position of the virtual objects 3 and 4 on the basis of the aforementioned correspondence 15.

For the visual impression 20, recourse is had here to the virtual objects 3 and 4, and so, for example, the stand 9 and also the markers 10, 17 are not displayed.

The field of view 19 of the head-mounted display 16 is defined here by a wearing position of the head-mounted display 16 on the head of a user and their natural field of vision.

In order to create the visual impression 20, the field of view data 21, the position and attitude data 22 from the second virtual space 12 and the object data 23 from the first virtual space 5 are schematically processed together in a manner known per se in FIG. 1.

In order to determine the field of view 19, the head-mounted display 16 can be equipped with its own sensors 46 which are not shown further here.

For example, the head-mounted display 16 may be equipped with a number of cameras that capture the field of view of a user of the head-mounted display 16 and calculate a position and attitude and/or a change in these values based on spatial features such as edges and room corners and the like. For this purpose, it is technically known to equip the head-mounted display 16 itself with appropriate computing capacity, so that no external computing capacity is required.

Since the real models 7 and 8 are set up in the real space 6, a user in the real space 6 can feel these real models 7 and 8, even if the head-mounted display 16 is of the VR glasses type and thus prevents the real models 7, 8 from being looked at.

In order to achieve a correspondence between this haptic impression and the visual impression 20, the real models 7 and 8 were initially aligned with the virtual objects 3 and 4 assigned to them.

The method according to the invention now allows a link 24 to be activated between the virtual objects 3 and 4 on the one hand and the corresponding virtual bodies 13, 14 on the other. As a result of this link 24, the virtual object 3, 4, in the example the virtual object 4, is concomitantly moved with the virtual body 13, 14, in the example the virtual body 14, using the correspondence 15.

Accordingly, if the real model 8 is modified by a movement 25, this movement 25 is reproduced in the second virtual space 12 by the 3D measuring device 11.

The situation with regard to direct following can also be changed so that only some axes follow along and some are “fixed”, for example in order to meet boundary conditions, as already mentioned.

The link 24 now causes the virtual object 4 in the first virtual space 5 to move equally according to the correspondence 15.

This leads to an apparent movement 26 in the visual impression 20.

The user producing the movement 25 by manipulating the real model 8 thus obtains the impression that, due to the manipulation, the virtual object 4 is performing an apparent movement 26.

If the link 24 is deactivated by the user or another person, manipulation of the real model 8 does not change the visual impression 20. This can be decided individually for the objects; it does not necessarily have to be so everywhere.

A head-mounted tracking device 27 is also arranged in the real space 6. The aforementioned user wears this head-mounted tracking device 27 like a glove in order to carry out the aforementioned manipulation on the real models 7, 8. Markers 28 on the head-mounted tracking device 27 are also represented by the 3D measuring device 11 as a virtual body 29 in the second virtual space 12, and so a hand replica 30 appears in the visual impression 20.

The head-mounted display 16 can be connected to a preferably stationary processing unit in a wireless or wired manner for the purpose of transmitting measurement data relating to the recording pose and/or image data for the visual impression 20.

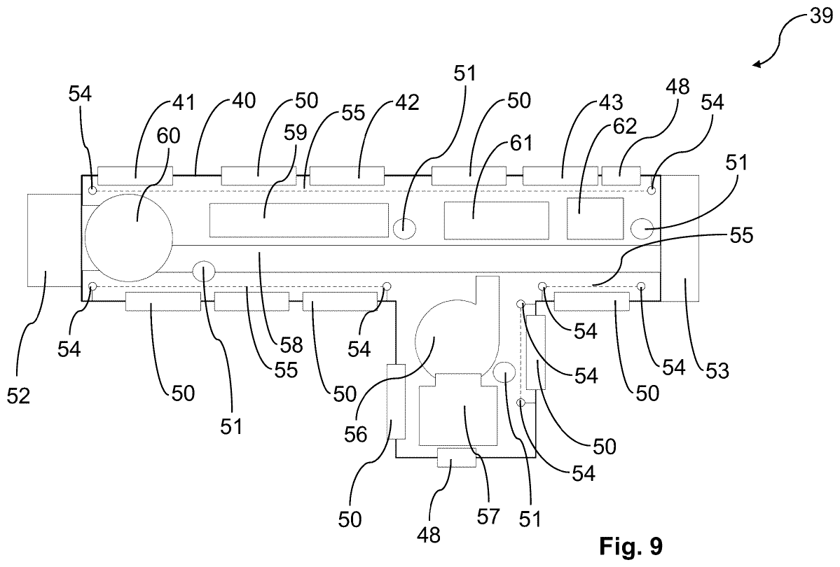

A 3D engine that is not represented further is used to create the visual impression 20. Said engine forms an apparatus for generating a field of view on the 3D model 39. An apparatus for isometrically transforming the 3D model 39 relative to the field of view 19 operates on the first virtual space 6, as is explained more precisely further below with reference to FIG. 8.

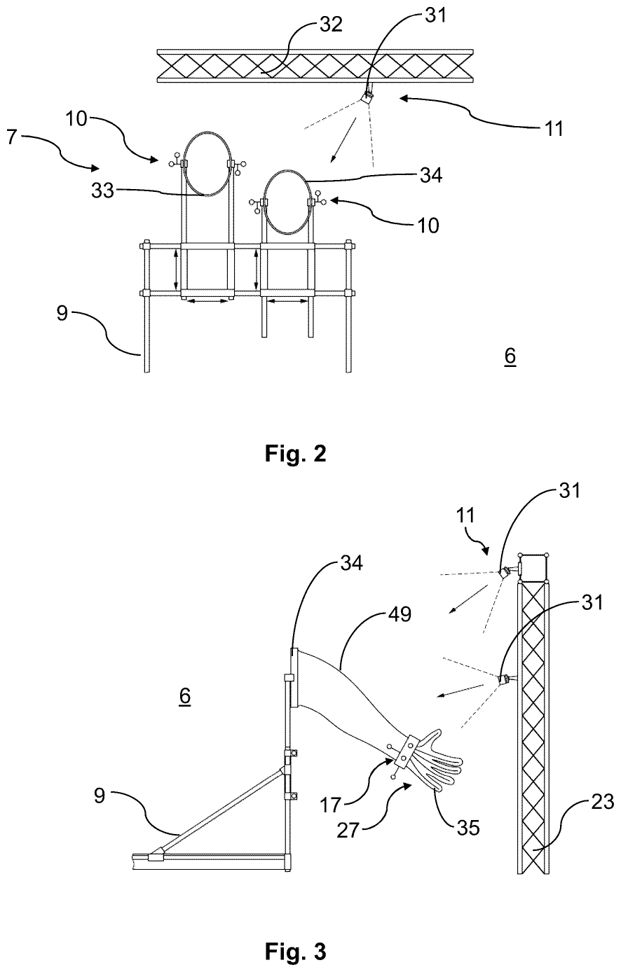

FIG. 2 shows a somewhat more realistic representation of the real model 7 from FIG. 1 in a representation from the front, and FIG. 3 shows this arrangement from the side.

Only sections of the 3D measuring device 11 are shown in both representations.

In fact, three or even more than five cameras 31 are typically arranged on a special carrier structure 32 in the real space 6.

The position and attitude of this camera 31 are precisely known.

In order to facilitate erection in situ, provision may be made for the fully assembled carrier structure 32 to be brought to the site of use in a container or in entirely packaged form. In this regard, the invention affords the advantage that it is not necessary to transport a model construction of the system. Rather, the carrier structure 32 constructed can be used as a mobile measuring set-up.

The real model 7 has two shoulder rings 33, 34, as are known on isolators for attaching isolator gloves 49. The shoulder rings 33, 34 are often formed in glass walls in the system. The position of the shoulder rings 33, 34 thus shows a position of a boundary of the system, for example a protected or controlled space.

The position of these shoulder rings 33, 34 on the stand 9 can be changed horizontally and vertically.

The hand tracking device 27 is connected to one of the shoulder rings 33, 34 for the purpose of forming an isolator glove 49.

The respective other shoulder ring 33, 34 may have a hand tracking device 27 for another hand of the user in a similar manner. During use, the user thus positions themselves in front of the shoulder rings 33, 34 and puts each of their two arms into one of these shoulder rings 33, 34 in order to use their hands to operate the respective hand tracking device 27.

In further exemplary embodiments, instead of the hand tracking device 27, the attitude and position or shape of the user's hand are captured using optical recognition algorithms.

The shape of the hand can also be captured using special sensors in the fingers 35, which will not be discussed further here.

For example, hand tracking devices 27 in the form of the “Quantum” METAGLOVES from Manus, Floor 9, Kennedyplein 200, NL-5611 ZT Eindhoven, are known and usable.

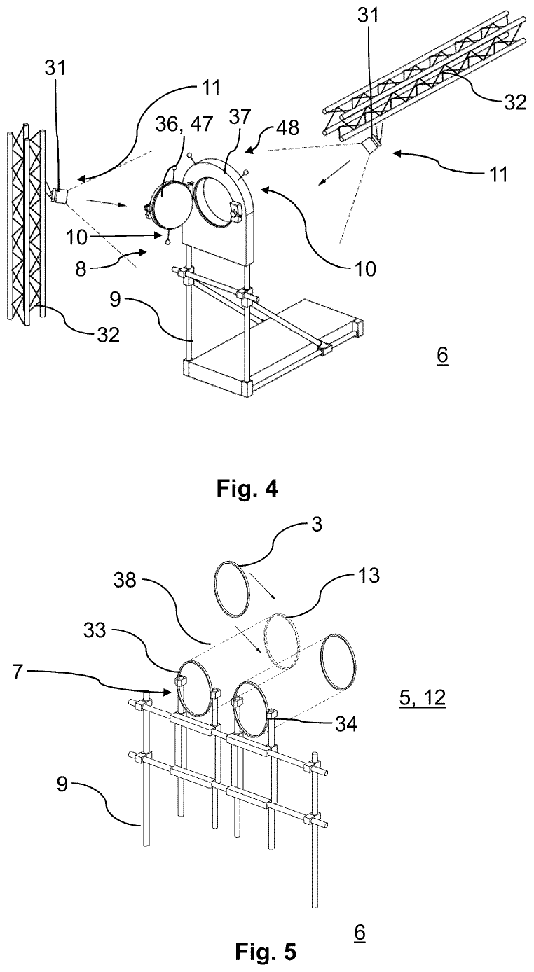

FIG. 4 shows a more realistic representation of the real model 8 from FIG. 1.

It is clear that the real model 8 consists of a moving part 36 and a stationary part 37.

The illustration shows by way of example a door 47, as can be used on a wall of an isolator, for example as a transfer port 48 or as rapid transfer port or in an airlock.

The details of this door 47 are irrelevant for the explanation of the invention; it is important solely that this transfer port 48 has a moving part 36 and a stationary part 37.

This moving part 36 can be gripped and opened by the user, in order to carry out the movement 25 mentioned in relation to FIG. 1.

This leads to the visual impression 20 displaying a change in the associated multi-part virtual object 4 that corresponds to the door 47 being opened.

The user can therefore check, for example, whether they can reach and operate a door 47 in an isolator through the shoulder rings 33, 34.

FIG. 5 shows the set-up of the already mentioned link 24 using the example of the shoulder rings 33, 34.

This set-up is carried out before the user starts the planned tests, in order to exactly coordinate the shoulder rings 33, 34 with their virtual equivalents.

The real model 7 is shown in the front row and an associated virtual body 13 is shown behind it using dashed lines and the associated virtual object 3 is shown using solid lines.

This representation has been selected for simplification. In fact, the real model 7, the virtual object 3 and the virtual body 13 are in different spaces 6, 12, 5.

The projection lines 38 between the real model 7 and the virtual body 13 are intended to symbolize the 3D measurement using the 3D measuring device 11.

When a request is made, the virtual object 3 is brought to a position that corresponds to the position of the virtual body 13 via the correspondence 15.

In order to support this process, provision may be made for both the virtual body 13 and the virtual object 3 to be rendered in the visual impression 20.

For the right-hand shoulder ring 34, this process has already been completed in FIG. 5.

Making the aforementioned request thus forces a desired positional relationship between the position and the attitude of the virtual object 3 in relation to the virtual body 13.

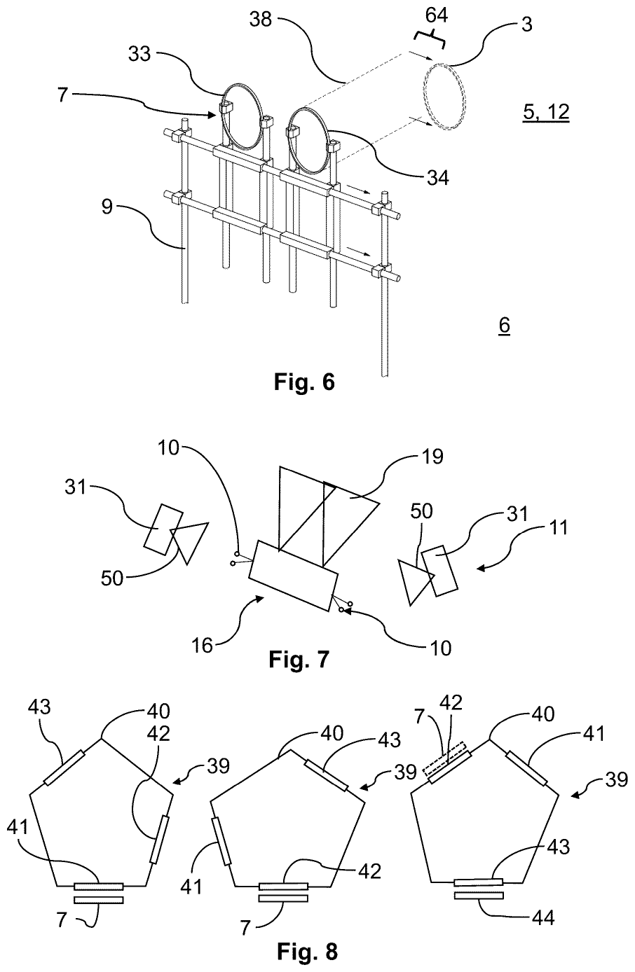

FIG. 6 shows the real model 7 in the foreground and the associated virtual object 3 in the background.

The projection lines 38 again illustrate the action of the 3D measuring device 11.

In order to simplify the representation, the virtual body 13 is not shown.

In the visual impression 20, the user now sees that the virtual object 3 and the virtual body 13, which is also shown, do not lie on top of each other.

The user or an assistant can now change the stand 9 in such a way that the virtual body 13 lies above the virtual object 3. The link 24 can then be activated. In comparison with the procedure according to FIG. 5, this procedure has the effect that the virtual object 3 is not changed by activating the link 24 and in particular remains unchanged in relation to other virtual objects 4.

Since the shoulder rings 33, 34 remain stationary, it is not necessary to activate the link 24, but rather it can be permanently deactivated.

The formation of individual links 24 between the virtual body 14 and the virtual object 4 allows the individual links 24 to be permanently deactivated for individual virtual bodies 13, 14. This allows such adjustments to be made independently of the other virtual objects 3, 4.

The real model 7 can be adjusted by motor here, for example until an automatically captured deviation 64 in a position and/or attitude of a virtual body 13, 14 (not shown, cf. FIG. 5) from a corresponding virtual object 3 is within a tolerance range.

For this purpose, the device shown has an apparatus for adjusting at least one real model 7, 8 by motor and an apparatus for preferably automatically determining a deviation 64 in a position and/or attitude of a virtual body 13, 14 from a corresponding virtual object 3, 4 and an apparatus for adjusting at least one real model 7, 8 by motor until an automatically and/or manually captured deviation 64 in a position and/or attitude of a virtual body 13, 14 from a corresponding virtual object 3, 4 is within a tolerance range.

FIG. 8 shows a schematic representation of a 3D model 39 of an industrial system, for example a pharmaceutical system.

The 3D model here has a wall 40, in which for example three entries 41, 42, 43 are arranged.

Each of these entries 41, 42, 43 can here include, for example, virtual equivalents of pairs of shoulder rings 33, 34.

The left-hand representation in FIG. 8 shows a position in which a real model 7 of the entry is made to coincide or brought into a desired positional relationship with the virtual equivalent using a method according to FIG. 6 or 5.

This state is used to test and verify the accessibility of the system, that to the 3D model 39, through this entry 41.

If another entry 42, 43 is now intended to be tested, the 3D model 39 can be isometrically transformed in particular relative to the virtual body 13 such that the further entry 42 can be made to coincide with the real model 7 or its virtual body 13. This changes the attitude of the 3D model 39 in the first virtual space 6 or the correspondence 15 between the first virtual space 6 and the second virtual space 12. The system can now be tested through this entry 42. This situation is illustrated in the middle part of the image in FIG. 8.

The right-hand part of the image shows a further real model 44 that may be set up in a separate real space 6 or in the same real space 6.

For this further real model 44, there is thus a further virtual body 14 which is generated either via the same 3D measuring device 11 or via a further 3D measuring device 11 if the further real model 44 is set up in another (real) space.

In this way, it is possible for the system to be tested by two users at the same time, without these users having to be in any real spatial relationship with each other.

These two users can perform, for example, a (virtual) handshake or check handovers or mutual obstructions.

When switching from the left-hand situation to the middle situation in FIG. 8, the link 24 between the entry 41 as a virtual object and the virtual body 13, 14 of the real model 7 is thus deactivated, in order to replace it with a link 24 between the same virtual body 13 and another entry 42 as a virtual object. During this production of the link 24, a tolerance range is specified, within which a link 24 is accepted without the virtual object 3 having to be changed.

The users can now test, for example, the packaging of drugs in the protected space, here an isolator.

The set-up discussed can thus be used to carry out a method for testing the function of a system composed of the virtual 3D model 39 with a multiplicity of virtual objects 3, 4, wherein, for selected virtual objects 3, 4, a real model 7, 8 that is as realistic as possible is respectively provided. For example, these real models 7, 8 are produced as a 3D print from the virtual objects 3, 4. The similarity should be so concordant here that an optical impression when touching the real model 7, 8 corresponds to a visual impression when viewing the virtual object 3, 4.

The 3D measuring device 11 now measures the real models 7, 8 at recurring times in order to align an associated virtual body 13, 14 accordingly in the second space 12.

In this case, the real models 7, 8 are provided with markers 10 in order to enable identification based on features. In order to make it possible to concomitantly convey the virtual objects 3, 4 provided that a link 24 is activated, correspondences 15 between these identified features, i.e. the markers 10, and the virtual objects 3, 4 are stored, and so virtual bodies 13, 14 can be moved with virtual objects 3, 4.

The virtual objects 3,4 can here contain predetermined positions, for example drill holes, to which the markers 10 are applied. This makes it possible to easily arrange the markers 10 at positions on the real models 7 and 8, so that the virtual body 13, 14 can be easily found and aligned with respect to the virtual object 3, 4.

Alternatively, the markers 10 can also be applied as desired to the real models 7, 8, and a position of the formed features, in particular the markers 10, on the real model 7, 8 can then be measured.

The method for testing the function of a system 1 can therefore begin by initially providing CAD data relating to the system by means of appropriate design, processing these CAD data to form a 3D model 39, generating real models 7, 8 for this 3D model 39 or some of the CAD data for selected details, in particular using 3D printing or an alternative manufacturing method, setting up these real models 7, 8 in a 3D measuring device 11, and displaying the 3D model 39 in the visual impression 20 from the observer's position.

If changes to the 3D model 39 are required during the test, for example according to the procedure from FIG. 5, these changes to the 3D model 39 can be output as modified design data at the end of the test. This may be the case, for example, if it has been found that certain details of the 3D model 39 are ergonomically unfavorable and therefore need to be revised in terms of design.

In the course of testing, the users can now manipulate the real models 7, 8 as desired in order to check their effects in the visual impression 20 at the level of the virtual objects 3, 4.

This is made possible by the link 24 which forces the virtual objects 3, 4 to be concomitantly conveyed with the associated virtual bodies 13, 14. In the presented exemplary embodiment, this is achieved with an apparatus for automatically concomitantly conveying the virtual objects 3, 4 with the associated virtual body 13, 14 and a 3D engine as an apparatus for visually displaying the 3D model 39.

FIG. 7 shows a head-mounted display 16 in a schematic representation with a 3D measuring device 11. This structure can be used in the structure according to FIG. 1, but can also be operated separately from the structure according to FIG. 1.

In this head-mounted display 16, the attitude and alignment of the field of view 19 are determined at recurring times, wherein concomitantly moving information, for example virtual objects 3, 4 in the manner described or other location-related information such as warnings or work instructions, are shown, for example in the visual impression 20.

In this case, the field of view 19 is determined using intrinsic, that is to say, for example, integrated, means of the head-mounted display 16. This results in this field of view 19 being able to be created only in relation to real models 7, 8 located in the field of view 19.

In order to also make it possible to align the head-mounted display 16 with respect to the other real models outside the field of view 19, the 3D measuring device is used to extrinsically determine an attitude and position of the head-mounted display 16 on the basis of markers 10. This information can then be associated with the field of view 19 in order to enable accurate and almost uninterrupted or completely uninterrupted capture of an attitude and a position of the head-mounted display 16 and thus a continuous visual experience in the visual impression 20.

It is known that controlled air flows are often used in isolators, inter alia, in controlled environments in order to be able to discharge potentially occurring contaminants in a controlled manner and to keep sensitive areas free of contaminants.

The present invention now makes it possible to calculate such air flows as flowlines 45 and to display their change, in particular in the case of movements 25, in the visual impression 20.

FIG. 9 shows a further virtual 3D model 39 for use in the invention. It is a pharmaceutical system having a wall 40, entries 41, 42, 43, 50, measuring stations 51, for example for measurement using agar plates and/or by means of particle measurement, a feed 52 from an automation, a discharge 53 to a further automation, light barrier modules 54 with light beams 55 for monitoring the entries 41, 42, 43, 50 for unexpected and/or unauthorized access, a sorting pan for providing stoppers or other components of packaging or medical dispensing devices in the correct position, a material supply 57 for the sorting pan 56, which is refillable, for example, via a transfer port 48, a transport and processing area 58, for example for processing (filling and sealing) containers (vials, etc.), a filling station 59 for filling containers, a separating station 60 for separating packages from containers supplied by the feed 52, a placement station 61 for sealing the containers with the aforementioned stoppers, and a checking station 62 for checking the filled and sealed containers.

Some of the components require haptic contact with a user during a functional test and are therefore used as a real model 7, 8. For example, this is not required for the sorting pan 56—here, a virtual object 63 is sufficient. On the other hand, it is advantageous to use a real model 7, 8 for the filling station 59 and the measuring stations 51. This can be an actual product instead of the 3D print already described. This can be easier for complex structures.

The light barrier modules 54 may also be present as real models 7, 8, but in functionless form, for example. In the virtual world, the light beam 55 is simulated and a check is carried out in order to determine whether a user virtually interrupts the light beam 55 and, if necessary, generates a signal.

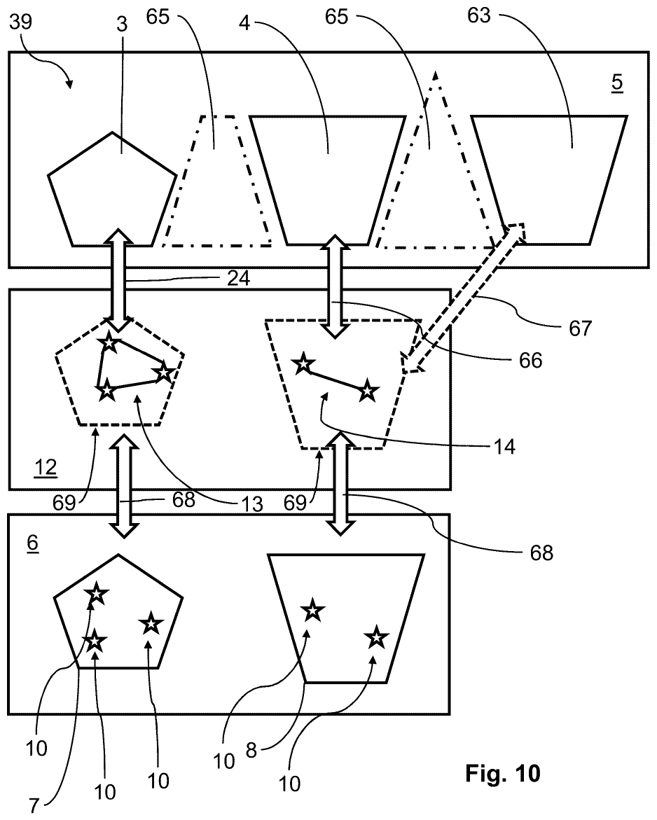

FIG. 10 shows a further virtual 3D model 39 for use in the invention. Components and functional units which are similar or identical functionally and/or structurally to preceding exemplary embodiments are denoted by the same reference signs and are not described separately. The explanations relating to the preceding exemplary embodiments therefore apply accordingly.

FIG. 10 additionally shows the concomitant conveying of the virtual body 13, 14 on the basis of the 3D measurements 68 on the real models 7, 8.

A set-up step defines the virtual object 3, 4, 63 to which a virtual body 13, 14 can be linked, indicated here by a contour 69 matching one or more shapes of the virtual objects 3, 4, 63. The virtual body 14 can thus be linked to at least two virtual objects 4, 63.

A virtual body cannot be linked to the virtual objects 65.

The set-up step also defines how a virtual object 3, 4, 63 can be linked to a virtual body 13, 14. This is expressed by a spatial relationship between the contours 69 and the positions of the markers 10 which correspond to the positions of the markers on the real model 7, 8.

The link 66 can be deactivated after set-up in order to activate a link 67 to the virtual object 63. From the change of this link, the virtual object 63 is concomitantly conveyed with the real model 8.

The link 24 between a virtual body 13 and the virtual object 3 can be activated or ended independently of the link 66 between a further virtual body 14 and a further virtual object 4, 63 (or the optionally activated link 67).

The number of virtual, in particular linkable, objects 3, 4, 63, 65 is greater than a number of virtual bodies 13, 14.

At least two real models 7, 8 are provided, wherein an associated virtual body 13, 14 is realized in each case.

The at least two real models 7, 8 are in a spatial relationship with each other, which is defined by a virtual spatial relationship between at least two virtual objects 3, 4, namely via the additional virtual objects 65 without a link. This spatial relationship is provided via the at least two virtual bodies 13, 14 which belong to the at least two real models 7, 8.

In this case, the at least two real models 7, 8 may be forcibly guided with respect to each other or absolutely or may be movable with respect to each other to a limited extent.

In the case of forced guidance or limitation, the mobility of a user is restricted during use by at least one real model 7, 8.

In the case of a method for testing the function of a system 1, it is therefore proposed to create real models 7, 8 from details of a virtual 3D model 39 of the system, the spatial position and attitude of which are captured using a 3D measuring device 11 during the functional test, wherein these specific attitudes and positions can be used to concomitantly convey virtual objects 3, 4 of the 3D model 39 in order to display a visual impression 20 in a virtual reality concomitant conveyance for manipulation of the real models 7, 8.

### List of Reference Signs

1 Device for testing the function of a system
2 Virtual 3D model
3 Virtual object
4 Virtual object
5 First virtual space
6 Real space
7 Real model
8 Real model
9 Stand
10 Marker
11 3D measuring device
12 Second virtual space
13 Virtual body
14 Virtual body
15 Correspondence
16 Head-mounted display
17 Marker
18 Virtual body
19 Field of view
20 Visual impression
21 Field of view data
22 Position and attitude data
23 Object data
24 Link
25 Movement
26 Apparent movement
27 Hand tracking device
28 Marker
29 Virtual body
30 Hand replica
31 Camera
32 Carrier structure
33 Shoulder ring
34 Shoulder ring
35 Finger
36 Moving part
37 Stationary part
38 Projection line
39 3D model
40 Wall
41 Entry
42 Entry
43 Entry
44 Further real model
45 Flowline
46 Sensor
47 Door
48 Transfer port
49 Isolator glove
50 Further entry
51 Measuring station
52 Feed
53 Discharge
54 Light barrier module
55 Light beam
56 Sorting pan
57 Material supply
58 Transport and processing area
59 Filling station
60 Separating station
61 Placement station
62 Checking station
63 Further virtual object
64 Deviation
65 Further virtual object
66 Link
67 Link
68 3D measurement

1. A method for testing the function of a system (1), wherein the system is represented as a virtual 3D model (2) comprising virtual objects (3, 4), wherein the virtual objects are characterized as a functional and/or design part of the 3D model, the method comprising:
providing at least one virtual object (3, 4) for a real model (7, 8),
aligning a virtual body (13, 14) with the real model (7, 8) at recurring times using a 3D position measurement, wherein the virtual body is constructed as a rigid body formed from measuring points in a fixed arrangement in relation to one another.
linking the at least one virtual object (3, 4) to the virtual body (13, 14) and bringing the at least one virtual object (3, 4) into a desired position relationship with the virtual body (13, 14), and
at least one of activating or starting or deactivating or ending the linking (24) between the virtual body (13, 14) and the at least one virtual object (3, 4) by a user, wherein the at least one of activating or starting or deactivating or ending of the linking between the virtual body (13, 14) and the at least one virtual object (3, 4) is independent of a linking between a further virtual body (13, 14) and a further virtual object (3, 4) of the at least one virtual object (3, 4).

2. The method as claimed in claim 1 the linking (24) of the virtual body (13, 14) to the at least one virtual object (3, 4) comprises forcing a desired positional relationship on at least one of a position or an attitude of the at least one virtual object (3, 4) in relation to the virtual body (13, 14), in response to at least one of a position or attitude thereof.

3. The method as claimed in claim 1, wherein a set-up step defines the at least one virtual object (3, 4) to which the virtual body (13, 14) is linked, and/or the set-up step defines how the at least one virtual object (3, 4) is linkable to the virtual body (13, 14).

4. The method as claimed in claim 3, further comprising setting up a linkability of the virtual body (13,14) to at least two of the virtual objects (3, 4).

5. (canceled).

6. The method as claimed in claim 1, wherein a number of the virtual, objects (3, 4) is not less or greater than greater than three times a number of the virtual bodies (13, 14).

7. The method as claimed in claim 1, wherein there are at least two of the real models (7, 8), and an associated virtual body (13, 14) is realized in each case.

8. The method as claimed in claim 1, wherein at least two of the real models (7, 8) are brought into a spatial relationship with each other, which is predefined by a virtual spatial relationship of at least two of the virtual objects (3, 4), by at least two of the virtual bodies (13, 14) which belong to the at least two real models (7, 8).

9. The method as claimed in claim 9, wherein the at least two real models (7, 8) are movable with respect to each other with at least one of forced guidance or in a limited way.

10. The method as claimed in claim 1, further comprising restricting mobility of a user during use by the real model.

11. The method as claimed in claim 1, further comprising deactivating the linking over a period of time, and displaying deviations between the at least one virtual object (3, 4) and the virtual body (13, 14) when the link (24) is deactivated.

12. The method as claimed in claim 1, wherein, wherein the linking (24) of the virtual body (13, 14) to the at least one virtual object (3, 4) is replaced by another linking of the virtual body (13, 14) to another virtual object of the at least one virtual object (3, 4).

13. The method as claimed in claim 12, wherein the 3D model (39) is subjected to an isometric transformation when the linking (24) is replaced by the other linking (24), until the virtual body (13, 14) and the other virtual object (3, 4) are made to coincide at least within a tolerance range.

14. The method as claimed in claim 13, further comprising changing an attitude of the real model (7, 8) until the associated virtual body (13, 14) is made to coincide with the virtual object (3, 4) or with the other virtual object, and then activating the linking (24) between the virtual body (13, 14) and the at least one virtual object (3, 4) or the other virtual object (3, 4).

15. The method as claimed in claim 1, wherein a plurality of the virtual bodies (13, 14) are linked to respective ones of the at least one virtual object (3, 4) of the 3D model (39), changing the individual links (24) independently of each other.

16. The method as claimed in claim 1, further comprising outputting an update of coordinates of the at least one virtual object (3, 4) for processing design data of the 3D model (39).

17. The method as claimed in claim 1, wherein the system for the pharmaceutical sector for filling drugs into packages.

18. A method for testing the function of a system (1), wherein the system is represented as a virtual 3D model (2) comprising virtual objects (3, 4), the method comprising:
providing at least one virtual object (3, 4) for a real model (7, 8)
aligning a virtual body (13, 14) with the real model (7, 8) at recurring times using a 3D position measurement and the at least one virtual object is linked to the virtual body (13, 14) and bringing the at least one virtual object into a desired positional relationship with the virtual body (13, 14), and
producing the real model (7, 8) corresponding to the at least one virtual object (3, 4) in an additive method and is provided with identifiable features for a 3D position measurement, and storing a correspondence (15) between the identified features and the at least one virtual object (3, 4).

19. The method as claimed in claim 18, wherein the identifiable features are formed at predetermined positions of the real model (7,8).

20. The method as claimed in claim 18, further comprising measuring at least one position of the formed features on the real model (7, 8).

21. The method as claimed in claim 18, further comprising an operator wearing a glove and/or a hand tracking device (27), and recurrently determining a 3D position of one or more fingers and/or a hand and/or an arm of the glove and/or the or a hand tracking device (27).

22. The method as claimed in claim 18, wherein the 3D model (39) represents a shoulder ring, to an attitude of which a real shoulder ring (33, 34) is adjusted, and/or wherein an operator inserts an arm through the shoulder ring (33, 34).

23. The method as claimed in claim 22, wherein the recording pose of the observer is defined relative to the shoulder ring (33, 34).

24. The method as claimed in claim 18, wherein the at least one virtual object (3, 4) is or has a door (47) of a transfer port (48).

25. The method as claimed in claim 18, wherein the 3D model (39) has a further virtual object (3, 4), for which a further real model (7, 8) is provided, and the method further comprises arranging the real model (7, 8) movably relative to the further real model (44).

26. The method as claimed in claim 25, wherein the further real model (44) is at least partially immobile and/or at least partially movable with respect to a demarcation of the system.

27. A method for testing the function of a system (1), comprising the following steps:
providing CAD data for the system,
creating at least one real model (7, 8) for at least some of the CAD data,
setting up the at least one real model (7, 8) in a 3D measuring apparatus (11),
displaying a virtual 3D model (2) created from the CAD data by processing at least 3D measurement data from the 3D measuring apparatus (11).

28. The method as claimed in claim 27, further comprising determining a field of view (19) of a head-mounted display (16) using the 3D measuring apparatus (11).

29. The method as claimed in claim 27, further comprising displaying the 3D model (39) with respect to a field of view (19) of a head-mounted display (16).

30. The method as claimed in claim 27, further comprising automatically reconstructing a change to the at least one real model (7, 8) on the 3D model (39), and generating and outputting modified design data from the modified 3D model (39).

31. The method as claimed in claim 27, further comprising transporting the 3D measuring apparatus (11) in a fixed measuring set-up prior to installation.

32. (canceled).

33. (canceled).

34. (canceled).

35. (canceled).

36. (canceled).

37. (canceled).

38. (canceled).

39. A method for visually displaying 3D data, the method comprising: intrinsically determining a field of view (19) of a head-mounted display (16) at recurring times and displaying information moving concomitantly with the field of view (19) in the head-mounted display (16) using a 3D measuring apparatus (11) that is formed independently of the head-mounted display (16) and/or is stationary, and determining a recording pose, predefining the field of view (19), of the head-mounted display (16) and comparing the recording pose with the field of view (19), and visually displaying the 3D data in the field of view (19) with a 3D engine.

40. The method as claimed in claim 39, wherein the recording pose is determined using the 3D measuring apparatus (11) that is stationary and comprises one or more cameras (31).

41. The method as claimed in claim 39, wherein the recording pose is determined using a measuring apparatus which moves concomitantly and/or is independent of the determining of the field of view (19).

42. The method as claimed in claim 39, wherein the intrinsic determination is carried out by at least one concomitantly moving sensor.

43. The method as claimed in claim 39, wherein the recording pose is measured by active markers (10, 17) on the head-mounted display (16).

44. The method as claimed in claim 39, wherein the recording pose is measured by passive markers (10, 17) on the head-mounted display (16).

45. The method as claimed in claim 39, wherein the recording pose is measured by a stationary measuring.

46. The method as claimed in claim 39, wherein the intrinsic determination of the recording pose is measured by concomitantly moving cameras (31) on the head-mounted display (16).

47. A method for visually representing a system, the method comprising: intrinsically determining a field of view (19) of a head-mounted display (16) at recurring times, and calculating and visually displaying an air flow as moving 3D data in the form of flow lines in the head-mounted display (16).

48. The method as claimed in claim 47, wherein the 3D data comprise at least one of a 3D model (39) of a system or AR metadata for components of the system.

49. The method as claimed in claim 47, further comprising superimposing a virtual display of the 3D data on a real field of view (19) using the head-mounted display (16), and shielding a real environment.

50. The method as claimed in claim 1, wherein the real model (7, 8) is adjusted by motor, and/or the real model (7, 8) is adjusted until a captured deviation (64) in a position and/or attitude of the virtual body (13, 14) from the corresponding virtual object (3, 4) is within a tolerance range.

51. The method as claimed in claim 1, further comprising a virtual light beam (55) and checking whether the virtual light beam (55) is interrupted.

52. (canceled).

53. (canceled).

54. (canceled).

55. (canceled).

56. (canceled).

57. (canceled).

58. (canceled).

59. (canceled).

60. (canceled).
